(19) United States
(12) Patent Application Publication
(10) Pub. No.: US 2012/0104464 A1
(43) Pub. Date: May 3, 2012

(54) P-PIXEL CMOS IMAGERS USING ULTRA-THIN SILICON ON INSULATOR SUBSTRATES (UTSOI)

(76) Inventors: James Robert Janesick, Huntington Beach, CA (US); Peter Alan Levine, West Windsor, NJ (US); John Robertson Tower, Yardley, PA (US)

(21) Appl. No.: 13/283,195

(22) Filed: Oct. 27, 2011

Related U.S. Application Data
(60) Provisional application No. 61/407,993, filed on Oct. 29, 2010.

(51) Int. Cl. H01L 27/146

(52) U.S. Cl. 257/223; 257/E27.139

(57) ABSTRACT

A CMOS image sensor is disclosed. The CMOS image sensor includes a semiconductor substrate having a surface. An epitaxial layer is grown on the surface. A p-type CMOS pixel formed substantially in the epitaxial layer. In one version of the CMOS image sensor, there exists a net n-type dopant concentration profile in the semiconductor substrate and the epitaxial layer which has a maximum value at a predetermined distance from the surface and which decreases monotonically on both sides of the profile from the maximum value within the semiconductor substrate and the epitaxial layer. In another version of the CMOS image sensor, there exists a net n-type dopant concentration profile in the semiconductor substrate and the epitaxial layer which has a maximum value at the surface and which decreases monotonically with increasing distance from the surface within the semiconductor substrate and the epitaxial layer.

### CROSS-REFERENCES TO RELATED APPLICATIONS

This application claims the benefit of U.S. provisional patent application No. 61/407,993 filed Oct. 29, 2010, the disclosure of which is incorporated herein by reference in its entirety.

### FIELD OF THE INVENTION

The field of invention is semiconductor device fabrication and device structure. More specifically, the field is fabrication and structure of PMOS semiconductor imaging devices that employ ultra thin silicon on insulator (UTSOI) substrates.

### BACKGROUND OF THE INVENTION

CMOS image sensors first came to the fore in relatively low-performance applications where shuttering was not required, scene dynamic range was low, and moderate to high noise levels could be tolerated. A CMOS sensor technology enabling a higher level of integration of an image array with associated processing circuits would be beneficial to many digital applications such as, for example, in cameras, scanners, machine vision systems, vehicle navigation systems, video telephones, computer input devices, surveillance systems, star trackers, motion detection systems, image stabilization systems and high-definition television imaging devices.

The advantages of CMOS imagers over CCD imagers are that CMOS imagers have a low voltage operation and low power consumption; CMOS imagers are compatible with integrated on-chip electronics (control logic and timing, image processing, and signal conditioning such as A/D conversion); and CMOS imagers allow random access to the image data. On-chip integration of electronics is particularly advantageous because of the potential to perform many signal conditioning functions in the digital domain (versus analog signal processing) as well as to achieve a reduction in system size and cost.

High performance for both CCD and CMOS imagers implies at least very low read noise (1-4 e−), high quantum efficiency (transmission limited), deep depletion for near IR and soft x-ray charge collection efficiency (CCE) performance, low pixel cross talk (high MTF), high charge transfer efficiency (CTE), high signal-to-noise ratio for low contrast scenes and very high speed/low noise parallel readout using integrated designs.

In a CCD imager, the electronic circuitry and gates are formed on one side of a silicon wafer, i.e., the front side; the other side of the wafer is the back side. When a CCD imager is illuminated on the front side, absorption of incident light by the electronic circuitry reduces quantum efficiency. As an alternative, CCDs may be illuminated from the back side; however, back side illumination produces other problems. When incident photons enter the back side of the CCD imager, they are absorbed in a silicon substrate and produce electronic charge by the photoelectric effect. Wafer thickness of the CCD imager must be sufficient to allow charge generation, and a depletion region should exist to transport the charge to collecting channels. For conventional low resistivity substrates, the thickness of the depletion region is limited to less than about 5 μm. Therefore, for good blue and ultraviolet response, the substrate must be extremely thin in order to have acceptable charge spreading (crosstalk), resulting in a very fragile and expensive structure.

Therefore, it is desirable to implement a back side illuminated CMOS imager that has a high quantum efficiency over a broad range of wavelengths, from infrared and red to blue and ultraviolet.

### SUMMARY OF THE INVENTION

The above-described problems are addressed and a technical solution achieved in the art by providing an improved readout circuit for a CMOS image sensor, comprising: a semiconductor substrate having a surface; an epitaxial layer grown on the surface with a net n-type dopant concentration profile, the profile having a maximum value of net n-type doping concentration proximal to the surface in one of the semiconductor substrate and the epitaxial layer and which decreases monotonically with increasing distance from the maximum value within one of the semiconductor substrate and the epitaxial layer; and a p-type CMOS pixel formed substantially in the epitaxial layer. In one version of the CMOS image sensor, the net n-type doping concentration decreases monotonically on both sides of the profile from the maximum value within at least one of the semiconductor substrate and the epitaxial layer. In another version of the CMOS image sensor, the net n-type doping concentration has a maximum at the surface and decreasing monotonically with increasing distance from the surface within the semiconductor substrate and the epitaxial layer.

According to an embodiment of the present invention, the p-type CMOS pixel may comprise: a highly p-doped sense node; a PMOS reset transistor in signal communication with the sense node; a PMOS source follower transistor in signal communication with the sense node; a PMOS row select transistor in signal communication with the source follower transistor; and a pinned-photodiode (PPD) in electrical communication with the sense node. The CMOS pixel may further comprise a first charge transfer gate located between the sense node and the PPD. The CMOS pixel may further comprise a second charge transfer gate located adjacent the phototransistor and distal to the first transfer gate and a highly p-doped contact for preventing charge carriers from blooming to the sense node.

According to an embodiment of the present invention, the CMOS image sensor may further comprise driver logic formed in the semiconductor substrate. The driver logic is at least one of an address encoder, a pixel bipolar driver, and a multiplexor.

According to an embodiment of the present invention, the CMOS image sensor may further comprise: a highly p-doped sense node in the semiconductor substrate and positioned substantially in the center of the at least one CMOS pixel; a transfer gate formed about the sense node; and at least one photodiode formed about the transfer gate. The CMOS image sensor may further comprise: a PMOS reset transistor in signal communication with the sense node; a PMOS source follower transistor in signal communication with the sense node; a PMOS row select transistor in signal communication with the source follower transistor; an a pinned-photodiode (PPD) in electrical communication with the sense node. The reset transistor, the source follower transistor, and the row select transistor are located substantially to one side of the at least one CMOS pixel substantially adjacent to the PPD. An implant may formed about the photodiode operable to step potential in a direction toward the sense node.

According to an embodiment of the present invention, the CMOS image sensor may further comprise: at least a portion of a buried oxide layer substantially underlying the semiconductor substrate distal to the surface.

### BRIEF DESCRIPTION OF THE DRAWINGS

The present invention may be more readily understood from the detailed description of an exemplary embodiment presented below considered in conjunction with the attached drawings and in which like reference numerals refer to similar elements and in which:

FIGS. 1A, 1B, and 1C are cross-sectional views of a p-type CMOS 3T, a 4T pixel, and a 5T pixel, respectively, according to an embodiment of the present invention;

FIG. 2A depicts a side view of a p-type 5T ring pixel, while FIG. 2B depicts a top-down view of the ring pixel, according to an embodiment of the present invention;

FIG. 3 is a cross-sectional view of a CMOS imager (hereinafter designated as a p_imager), according to an embodiment of the present invention;

FIG. 4 shows a process for fabricating an imaging device on a UTSOI substrate, according to an embodiment of the present invention;

FIG. 5 shows an initial doping profile in a semiconductor substrate, before growth of an the epitaxial layer;

FIG. 6 shows a doping profile following growth of an epitaxial layer;

FIG. 7 shows the doping profile of FIG. 6 on a larger distance scale; and

FIG. 8 shows a doping profile following the growth of an epitaxial layer to produce a “dead band,” according to an embodiment of the present invention.

It is to be understood that the attached drawings are for purposes of illustrating the concepts of the invention and may not be to scale.

### DETAILED DESCRIPTION OF THE INVENTION

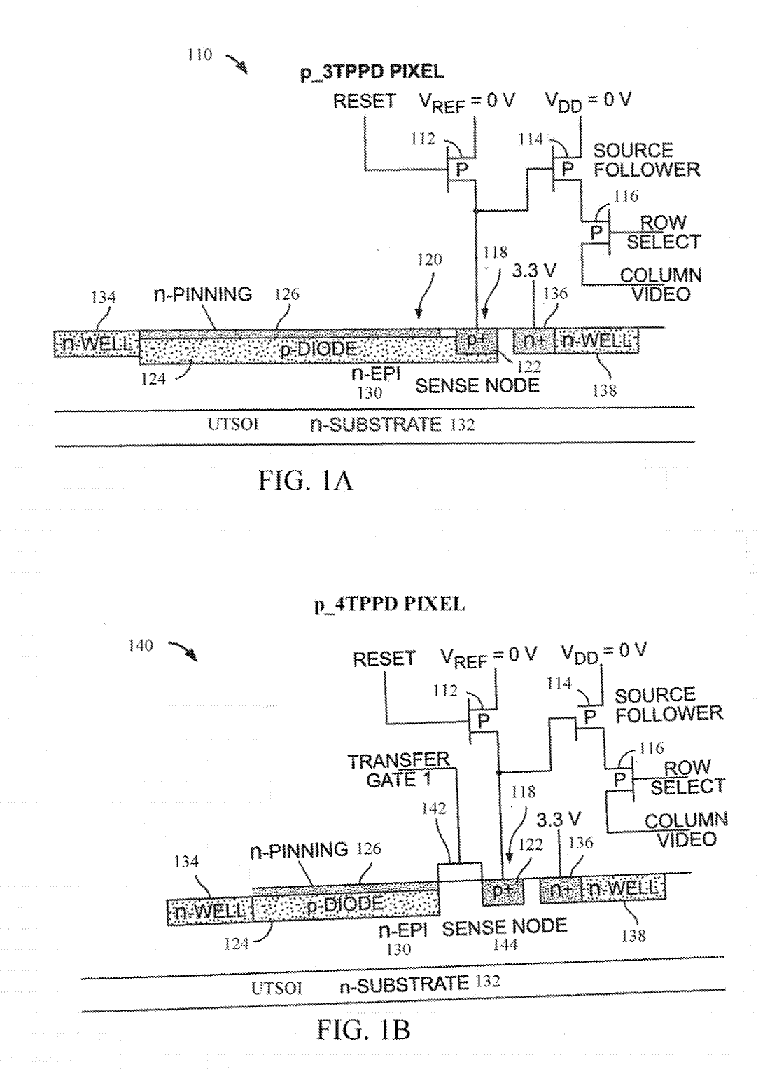

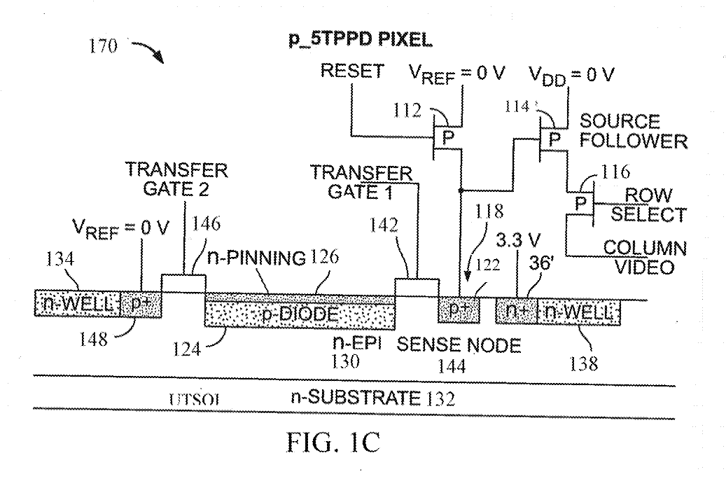

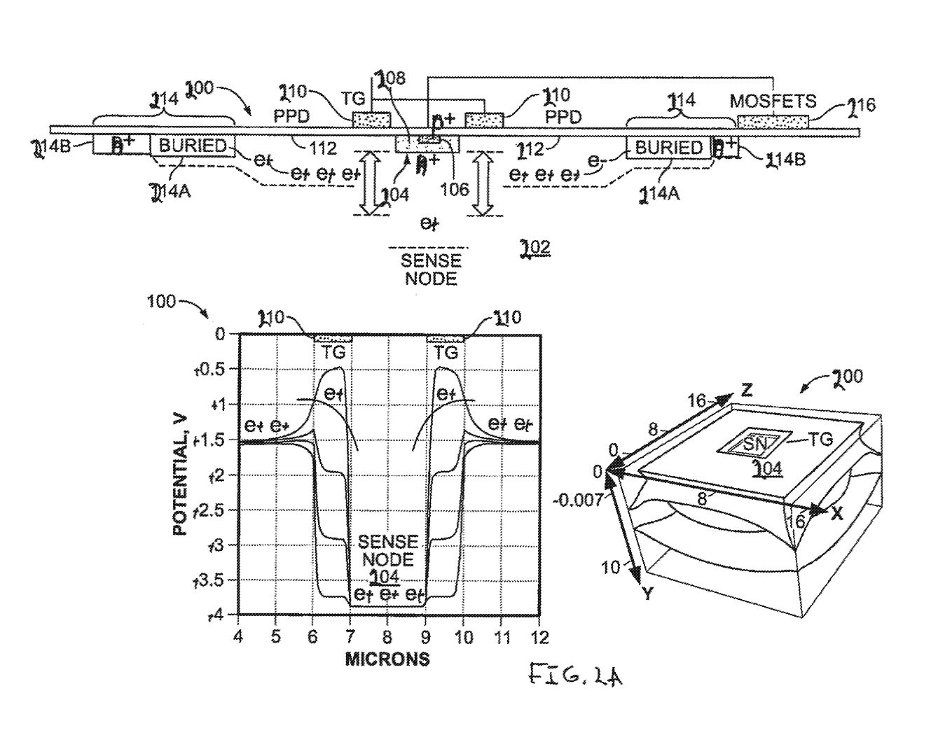

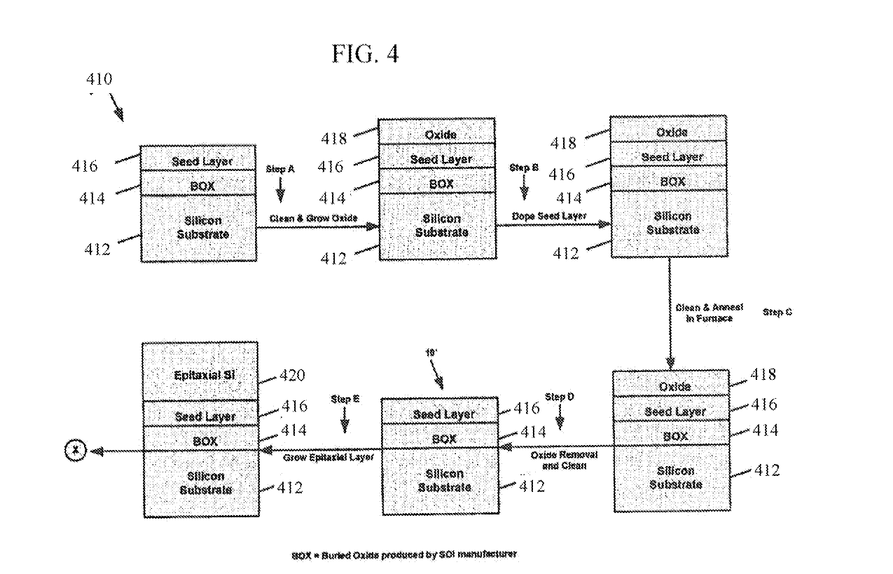

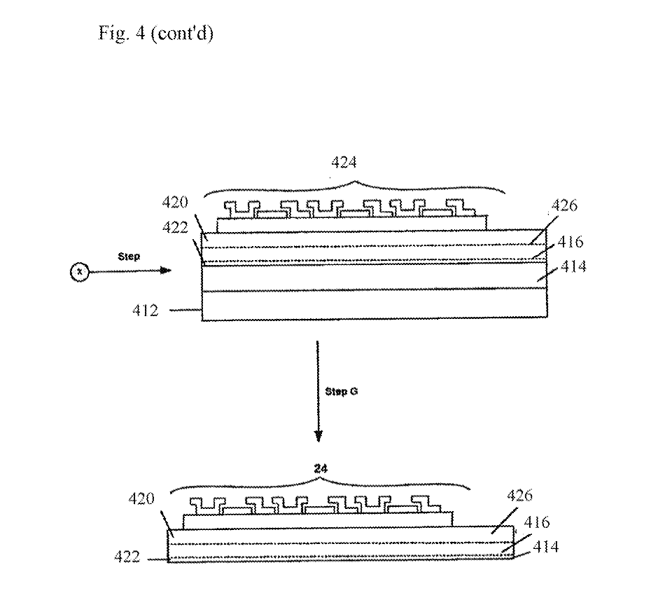

FIGS. 1A, 1B, and 1C are cross-sectional views of a p-type CMOS 3T pixel 110 (for three-transistor pixel), a 4T pixel 140 (for 3-transistor plus 1-transfer gate pixel), and a 5T pixel 170 (for 3-transistor plus 2-transfer gate pixel), respectively, according to an embodiment of the present invention. The p-type CMOS pixels are hereinafter designated as p_{—}3TPPD, p_{—}4TPPD and p_{—}5TPPD pixels, 110, 140, 170, respectively (collectively referred to as p_pixels). The p_{—}3TPPD pixel 110 includes three PMOS transistors 112, 114, 116 standing for a reset transistor 112, a source follower transistor 114 and a row transistor 116. The reset transistor 112 is electrically connected to a sense node 118. The sense node 118 is formed of a p+ contact 122 and a pinned photodiode 120. The pinned photodiode 120 includes a thin n-type pinning layer 126 overlying a custom p-diode implant 124, that in turn, overlies and forms a depletion region with an n-epitaxial layer 130. An ultra-thin silicon-on-insulator substrate (UTSOI) 132 underlies the n-epitaxial layer 130, the construction of which will be described hereinbelow with reference to FIGS. 4-7. An n-well 134 is formed adjacent the pinned photodiode 120 in the n-epitaxial layer 130 for isolating the p_{—}3TPPD pixel 110 from neighboring pixels. An n+ return contact 136 is formed proximal to the other side of the pinned photodiode 120 and is held at “high” potential (about +3.3V) for providing a return and reference for the p_{—}3TPPD pixel. An n-well 138 is formed adjacent to the p+ return contact 136.

When operated, a RESET CLOCK (about 0 V) applied to the gate of the reset transistor 112 causes a reverse bias on the pinned photodiode 120. The source follower transistor 114 and the row transistor 116 are coupled between a drain supply V_{DD} of about 0V and an output signal terminal COLUMN VIDEO. The drain of the reset transistor 112 is connected to V_{DD}; the gate of the reset transistor 112 is connected to a RESET clock; and the source of the reset transistor 112 is connected to the anode of the pinned photodiode 120 so that the reset transistor 112 operates as a source follower. The source of the source follower transistor 114 is connected to the drain of the row transistor 116, and the source of the row transistor 116 is connected to output terminal COLUMN VIDEO. In applications, a plurality of such 3T pixels is coupled to the same output terminal COLUMN VIDEO. By selectively applying row address signal ROW SELECT to the gate of the selected row transistor 116, different rows may be coupled to the output terminal COLUMN VIDEO (i.e., a column bus).

The p_{—}4TPPD pixel 140 (FIG. 1B), also known as a charge transfer pixel, is similar to the p_{—}3TPPD pixel 110 (FIG. 1A) except that the p_{—}4TPPD pixel 140 has a transfer gate 142 coupled between the reset transistor 112 and the pinned photodiode 120 so that a sense node 144 may be created between the transfer gate 142 and the reset transistor 112. The sense node 144 may be isolated from the pinned photodiode 120. As a result, charge may be transferred from a photodetection region to the sense node 144 when a “logical 0” or “low” ground potential of about 0V is applied to the input TRANSFER GATE 1, where a resulting voltage is read out by the source follower transistor 114.

The p_{—}5TPPD pixel 170 (FIG. 1C), is similar to the p_{—}4TPPD pixel 140, but includes a second transfer gate 146 abutting the side of the pinned photodiode 120 distal to the transfer gate 142. A p+ contact 148 is formed adjacent to the second transfer gate 146 distal to the pinned photodiode 120′ and is tied to V_{REF} (about 0 volts). The second transfer gate 146 may be used as a global reset for the imager and as an antiblooming gate for preventing excess charge generated in the photodiode 120 from “blooming” through the transfer gate 142 to the sense node 144 when a voltage is applied to the input TRANSFER GATE 2 that is more negative than the transfer gate-to-sense node voltage.

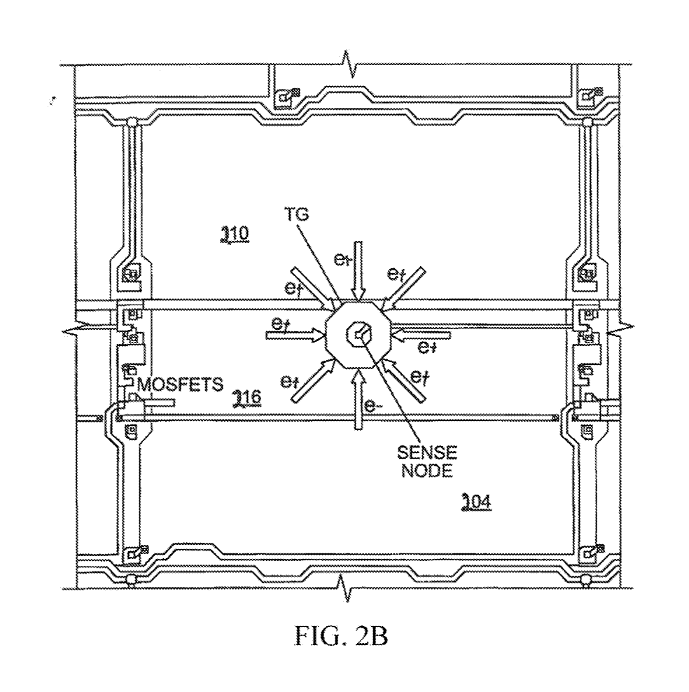

FIG. 2A depicts a side view of a p_{—}5TPPD ring pixel 200, while FIG. 2B depicts a top-down view of the ring pixel 200, according to an embodiment of the present invention. The ring pixel 200 includes a sense node 204 formed in the epitaxial layer 202 substantially in the center of the ring pixel 200. The sense node 204 comprises a highly doped p+ region 206 formed in a highly doped n+ region 208 (hereinafter the n-well 208). A ring shaped transfer gate 210 is formed about the sense node 204. A ring shaped pinned photo diode (PPD) 212, is formed about the ring shaped transfer gate 210. An optional ring shaped implant 214 comprising a buried channel 214A and a n+ region 214B may be formed about the ring shaped PPD 212 for generating a small ‘potential step’ to help positive charge (i.e., holes) move towards the ring shaped transfer gate 210. The optional ring shaped implant 214 may be used for very large pixels that need this assistance. Read MOSFETS 216 abut one side of the n+ regions 214B.

Referring now to FIG. 2B, the ring-based architecture of the ring pixel 200 is configured so that charge (in this case holes) is transferred from all directions originating from the ring shaped PPD 212 through the ring shaped transfer gate 210 to the central sense node 204 (indicated by the arrows 218), thereby reducing charge transfer time.

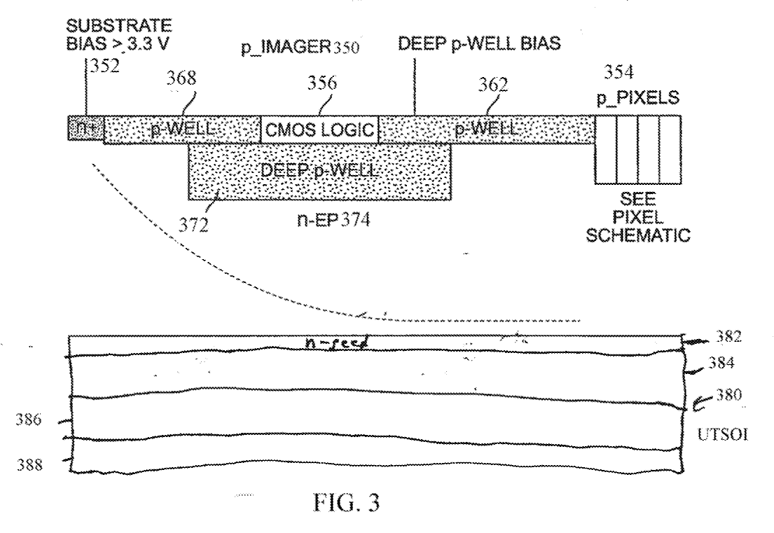

FIG. 3 is a cross-sectional view of a CMOS imager 350 (hereinafter designated as a p_imager 350), according to an embodiment of the present invention. The p_imager 350, in a preferred embodiment shown, includes a substrate bias contact 352 having an n+ polarity and a plurality of p_pixels 354. The p_imager 350 includes driver logic 356 for the p_pixels 354. The CMOS driver logic 356 may include digital logic elements (e.g., address encoders, pixel bipolar drivers, multiplexers, etc.). The p_pixels may be any of those described hereinabove in FIGS. 1A-1C and 2A-2B. A person skilled in the art would appreciate that the p_imager 350 is not strictly limited to the p_pixels of FIGS. 1A-1C and 2A-2B, but is equally applicable to designs with any type of p_pixel.

The p_pixels 354 are separated from the CMOS driver logic 356 by a p-well 362. A p-well 368 separates the n+ substrate bias contact 352 from the CMOS driver logic 356 distal to the p-well 362. The p well 362 may have a separate DEEP p-well bias of about 0 volts. The p-wells 362, 368 provide access contacts for biasing a deep p-well implant 372 to be described hereinbelow. The p-well 362 closest to the p_pixels 354 surrounds the entire pixel region (not shown) to form a depletion region around the edge of the p_pixels 354 to ensure that the p_pixels 354 pinch off substrate bias in proximity to the n+ return contact (not shown).

The p-wells 362, 368 naturally come with fabrication. A p-well is everywhere on a wafer containing at least one p_imager 350, unless another layer is intentionally implanted. An n-well is one such layer, which is only used when required. This is the difference between n and p-well. There is never a naked silicon surface, since it must be passivated. According to an embodiment of the present invention, p-well is chosen for passivation.

The substrate bias contact 352, the p_pixels 354, and the wells 362, 368, 372 may be formed in an n-type epitaxial layer 374, preferably made of silicon, which in turn is formed overlying a UTSOI substrate 380. The UTSOI substrate 380 comprises a seed layer 382 of the same conductivity type (n-type) as the epitaxial layer 374. The UTSOI substrate 380 further comprises an insulator layer 384, preferably made of an oxide of silicon (also known as a buried oxide (BOX) layer). The insulator layer 384 may optionally overly at least a portion of a mechanical substrate 386 and/or one or more layers of an antireflective coating 388. The p_imager 350 may be manufactured according to the methods described hereinbelow in connection with FIGS. 4-8.

U.S. patent application Ser. No. 11/350,546, filed on Feb. 9, 2006, now U.S. Pat. No. 7,238,583 (“the Swain et. al. '583 patent”), which is incorporated herein by reference in its entirety, describes a method for producing a back-illuminated imaging device that employs an ultra thin Silicon-on-Insulator (UTSOI) technology for providing a semiconductor substrate on which a back-illuminated imager is constructed. The practical work flow for using the method of Swain et al. in production is shown in FIG. 4.

In FIG. 4, the starting structure is an initial substrate 410, sometimes referred to in the art as an ultra-thin semiconductor-on-insulator (UTSOI) substrate. The starting UTSOI substrate 410, is composed of a mechanical substrate 412 (handle wafer) to provide mechanical support during processing, an insulator layer 414 (which can be, for example, a buried oxide layer of silicon (BOX)), and a semiconductor substrate 416 (seed layer). The mechanical substrate 412 is made of silicon in a preferred embodiment. Other semiconductor materials may be used. In step “A,” the UTSOI wafer 410 is cleaned and then an oxide layer 418 is grown overlying the seed layer 416 opposite the mechanical substrate 412. In step “B,” semiconductor substrate 416 is doped. Dopants are introduced into semiconductor substrate 416 in sufficient concentration to produce a desired net doping profile. The initial net doping concentration in semiconductor substrate 416 may be on the order of 10¹⁷ charge carriers per cubic centimeter or higher, and may be either p-type or n-type. Common dopants include boron, phosphorous, antimony, and arsenic.

The dopant is incorporated within the semiconductor before the growth of the epitaxial layer. Although the Swain et. al. '583 patent outlines several techniques for introducing the dopant, in order to practice the method of the Swain et. al. '583 patent using ultra-thin layers of semiconductor, the preferred method for introduction of dopants is through the use of ion-implantation. In Step “B,” ions of a dopant are implanted ballistically through the oxide layer 1618 into the seed layer 416 of UTSOI wafer 1610. In Step “C,” the UTSOI wafer 410 is cleaned and annealed in a furnace to remove the damage introduced by the ion implantation of dopants, i.e., broken bonds are reformed and dopants are incorporated at lattice sites. In Step “D,” the oxide layer 418 is removed and the resulting doped wafer 410 is cleaned. In Step “E,” an epitaxial layer 420 is grown overlying doped semiconductor substrate 416, using semiconductor substrate 416 as the template. The epitaxial layer provides a layer for fabricating front side components which complete the overall imaging device. Still referring to FIG. 4, during the growth of epitaxial layer 420, dopants previously introduced into semiconductor substrate 416 diffuse into epitaxial layer 420 as a result of processing at or above 1000° C. At the conclusion of the growth of the epitaxial layer 420, the net doping profile is very close to the desired profile, in that at each distance from interface 422 between the insulating layer 414 and the semiconductor substrate 416, within the semiconductor substrate 416 and epitaxial layer 420, the net carrier concentration is close to its final desired value. All remaining steps in the process are then carried out at lower temperatures, so that relatively little diffusion of dopants takes place, and the profile is essentially unchanged at the end of the process.

In Step “F,” once epitaxial layer 420 is grown, with the simultaneous formation of a desired dopant profile, one or more imaging components 424 (i.e., the top layer components of the p_imager 450 hereinabove) may be fabricated using known methods of semiconductor fabrication.

In Step “G,” the mechanical substrate 412 is removed. Once the fabrication of components 424 is complete, the mechanical substrate 412 is no longer needed to provide mechanical stability. Removal of mechanical substrate 412 may also be desirable in order to allow the emanation being detected to reach the backside semiconductor. Removal of mechanical substrate 412 may be accomplished by such methods as chemical etching, mechanical grinding, or a combination of these methods. With chemical etching, mechanical substrate 412 may be removed selectively, without removing insulator layer 414. Alternatively, at least a portion of mechanical substrate 412 may be left in place (not removed) if the remaining portion at least partially transmits the radiation or particles being detected and imaged.

If mechanical substrate 412 is entirely removed, insulator layer 414 may be removed, either partially or entirely, by chemical or physical methods or a combination of the two. In one embodiment, insulator layer 414 is made to act as an anti-reflection coating for electromagnetic waves having wavelengths in a predetermined range, thereby allowing more photons to reach, and be absorbed in, the semiconductor layers 416, 420. This may be accomplished by reducing thickness of insulator layer 414 to a thickness which minimizes reflection in the predetermined wavelength range. The thickness may be determined by the wavelength range and the index of refraction of the material of layer 414 in this wavelength range.

After partially removing the insulator layer 414, one or more anti-reflective coating layers (not shown) (for example, zirconium oxide or bismuth oxide) can be deposited on the insulation layer 414 to function as an overall anti-reflective coating stack for a desired range of wavelengths. In still other embodiments, the insulation layer 414 can be completely etched away, and one or more anti-reflective coating layers can be deposited on the semiconductor substrate 416 so as to function as an overall antireflective coating.

Referring again to FIG. 4, a goal of the process for manufacturing a back illuminated imaging device described in the Swain et. al. '583 patent is the creation of a final net dopant concentration profile in semiconductor substrate 416 and epitaxial layer 420 which has a maximum value at the interface 422 between semiconductor substrate 416 and insulator layer 1614. The final net dopant concentration profile after the epitaxial growth step “E” decreases monotonically with increasing distance from the interface 422 within a portion of semiconductor substrate 416 and epitaxial layer 420 between interface 422 and p-n junctions 456 shown in FIG. 4 (p-n junctions 426 are created during fabrication of the front-side components 424). Such a profile may give rise to an electric field within semiconductor substrate 416 and epitaxial layer 420 tending to drive photo-generated electrons toward the front side imaging components 424 and minimizing the trapping of these electrons near the backside.

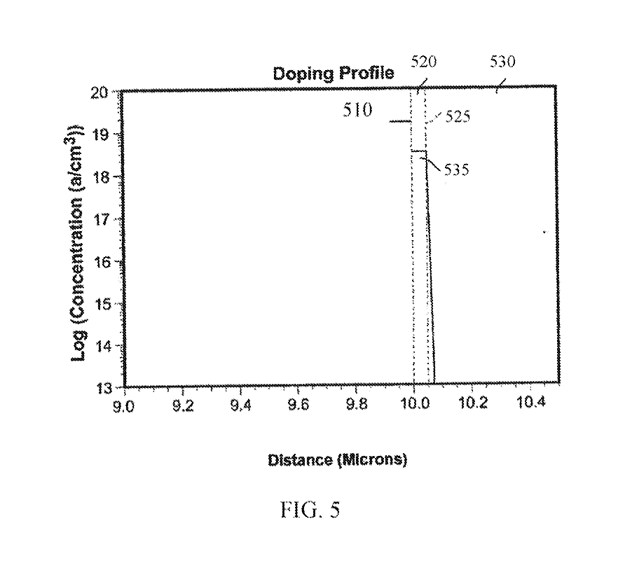

Processing parameters such as doping levels, initial doping profiles, and temperatures are chosen to give the desired doping profile, as described above. FIGS. 5 through 7, reproduced from the Swain et. al. '583 patent, show the results of computer simulations of desired net doping profiles. In these figures, various regions correspond to regions of the structures shown in FIG. 4, as follows:

Region 550 corresponds to the mechanical substrate 412. Region 530 corresponds insulator layer 414, comprising an oxide of silicon. Region 520 corresponds to semiconductor substrate 416, comprising silicon. Region 500 corresponds to epitaxial layer 420, comprising silicon. Number 525 corresponds to the interface 422 between semiconductor substrate 516 and insulator layer 414. Number 510 corresponds to interface an interface between semiconductor substrate 416 and the epitaxial layer 420.

FIG. 5 shows an initial doping profile 535 in semiconductor substrate 520, before growth of the epitaxial layer 500. Initial profile 535 is created by net n-type doping with a net n-type concentration of about 1×10¹⁹ carriers per cubic centimeter, assumed uniform through semiconductor substrate 520.

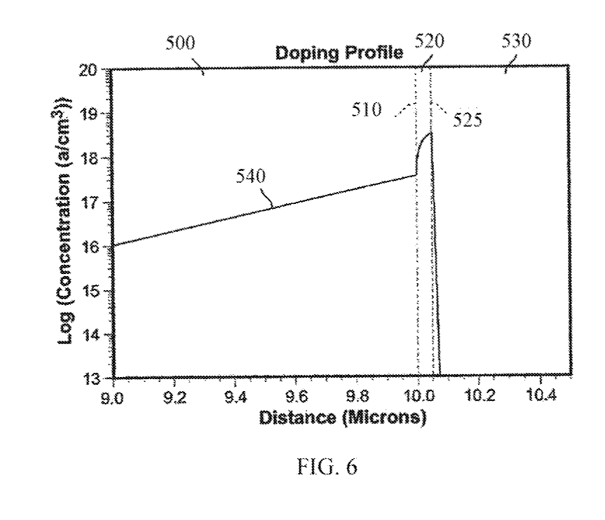

FIG. 6 shows a net final doping profile 540 after growth of epitaxial layer 500. The net profile 540 in this embodiment is n-type. Atoms starting in the semiconductor substrate 520 diffuse into epitaxial layer 500 during growth of that layer to produce what may become essentially final profile 540, as discussed above. Profile 540 in this simulated process has desired features: it has a maximum value at interface 525 of the semiconductor substrate 520 and the insulator layer 530 and decreases monotonically with increasing distance from interface 525 within semiconductor substrate 520 and epitaxial layer 500.

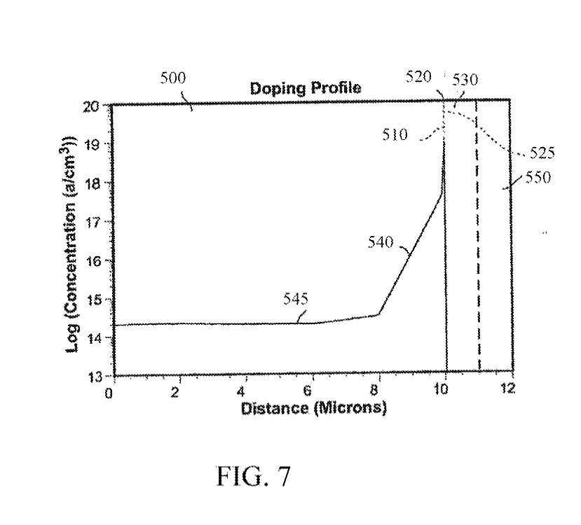

FIG. 7 shows the same doping profile as FIG. 6 on a larger scale of distance, in order to show essentially the entire profile. At some distance from interface 525 the monotonically decreasing portion 540 of the profile meets the background doping level 545 in the epitaxial layer 500. The doping level remains at this value 545 all the way to the junctions (not shown in FIG. 6). As long as net doping concentration 540, 545 does not increase with distance away from interface 525, carriers generated in the semiconductor substrate 520 or epitaxial layer 500 by waves or particles incident on the backside may tend to be driven toward imaging components 545 and not in the opposite direction.

One of the concerns expressed about high-resolution imaging devices made using technology that is similar to that disclosed in the Swain et. al. '583 patent is the potential presence of dark current. Dark current is the generation of carriers (electrons or holes), exhibited by a back-illuminated imager during periods when the imager is not actively being exposed to light. Dark current is detrimental to back-illuminated imager operation because excess dark current signal collected along with a desired optically generated signal results in higher levels of fixed pattern and excess random shot noise. The offset signal produced by dark current is seen as a non-uniform shading in a displayed image.

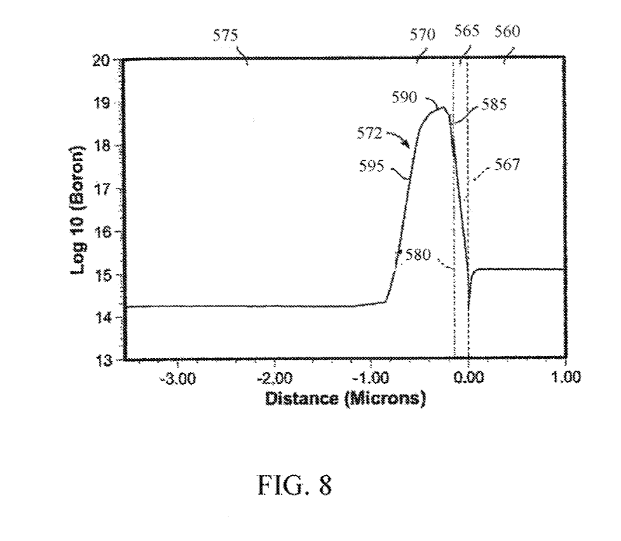

A solution to the dark current problem is described in U.S. Pat. No. 7,723,215 (the “Levine et al. '215 patent”), which is a continuation-in-part of the '583 patent, and is incorporated herein by reference in its entirety. Referring now to FIG. 8, there is shown a desired net doping profile 572 for a back-illuminated imaging sensor fabricated on Silicon-on-Insulator (SOI) which is designed for the reduction of dark current. Unlike the doping profiles shown in FIGS. 4-7, the net doping profile of FIG. 8 has a peak 590 a predetermined distance from the interface 580 between the insulating (buried oxide) layer 565 and the seed layer 570 (inside the region 570). The doping level, which can be n-type, increases monotonically beginning at the interface 580 between the insulator layer 565 and the seed layer 570. The doping profile continues to increase monotonically in the region 585, known as the dead band, until reaching a peak 590 within the seed layer 570 before monotonically decreasing, shown by the curve 595 inside the regions 570, 575 corresponding to one or both of the seed layer 516 and the epitaxial layer 520 of FIG. 4. The desired net doping profile 572 can be approximately Gaussian in shape.

Both dark current electrons and signal electrons can be influenced by the dead band-generated electric field. Processing parameters and the range of wavelength of operation are chosen to allow signal electrons to pass the dead band peak 590 toward the front side imaging components 524 while preventing dark current electrons from penetrating this barrier. The potential barrier corresponding to the doping maximum 590 should be large enough to prevent thermionic emission of dark current from moving past the doping peak 590 into the regions 570, 575. To assure negligible thermionic emission of dark current electrons over the potential barrier peak 590, the barrier peak voltage level in a preferred embodiment is about 10 times greater than kT, but may range from about 3 to 30 times greater than kT, where k is the Botzmann constant and T is absolute temperature in Kelvins. For signal electrons to get past the barrier peak 590, the absorption depth of incident signal photons, which depends on their wavelength, needs to be greater than the distance of the peak 590 from the interface 580 between the seed layer 570 and the insulator layer 565.

The dead band can be created by ion-implantation method previously described in FIG. 4, or by custom doping during epitaxial growth on a seed layer 516. In FIG. 8, instead of growing a second oxide layer overlying the seed layer 570 and then performing ion implantation through the second oxide layer, the dead band profile 572 can be obtained by growing an epitaxial layer 575 directly on the seed layer 570 and varying the doping concentration appropriately, as can be appreciated by those skilled in the art.

The methods for manufacturing a back illuminated imager based on either of the Swain et. al. '583 patent or the Levine et al. '215 patent requires several cleaning steps, which may leave residue on the ultra thin silicon surface. Residue is undesirable because it can result in unwanted image artifacts. A method for producing devices similar to that disclosed in the Swain et. al. '583 patent the Levine et al. '215 patent with improved characteristics and fewer processing (cleaning) steps is described in copending U.S. patent application Ser. No. 12/472,722 filed May 27, 2009 (hereinafter “the Zhu et al. '722 application), the disclosure of which is incorporated by reference in its entirety.

In summary, among the Swain et. al. '583 patent the Levine et al. '215 patent and the Zhu et al. '722 application, in one embodiment, at completion of the growing of the epitaxial layer, there exists a net dopant concentration profile which has an initial maximum value at an interface between the seed layer and the insulator layer and which decreases monotonically with increasing distance from the interface within at least a portion of at least one of the seed layer and the epitaxial layer. The net dopant concentration profile may have a slope which decreases monotonically at a first average rate within the semiconductor substrate, and decreases monotonically at a second average rate that is slower than the first average rate within the seed layer.

In another embodiment, at completion of the growing of the epitaxial layer there exists a net dopant concentration profile which has a maximum value at a predetermined distance from the interface between the insulator layer and the seed layer and which decreases monotonically on both sides of the profile from the maximum value within one of the seed layer and the epitaxial layer. The doping profile between the interface with the insulation layer and the peak of the doping profile functions as a “dead band” to prevent dark current carriers from penetrating to the front side of the device. The net dopant concentration profile may have a slope which decreases monotonically at a first average rate within the semiconductor substrate on a side of the doping profile that is distal to the interface between the insulator layer and the seed layer, and decreases monotonically at a second average rate that is slower than the first average rate within the seed layer.

It is to be understood that the exemplary embodiments are merely illustrative of the invention and that many variations of the above-described embodiments may be devised by one skilled in the art without departing from the scope of the invention. It is therefore intended that all such variations be included within the scope of the following claims and their equivalents.

What is claimed is:

1. A CMOS image sensor, comprising:
a semiconductor substrate having a surface;
an epitaxial layer grown on the surface with a net n-type dopant concentration profile, the profile having a maximum value of net n-type doping concentration proximal to the surface in one of the semiconductor substrate and the epitaxial layer and which decreases monotonically with increasing distance from the maximum value within one of the semiconductor substrate and the epitaxial layer; and
a p-type CMOS pixel formed substantially in the epitaxial layer.

2. The CMOS image sensor of claim 1, wherein the net n-type doping concentration decreases monotonically on both sides of the profile from the maximum value within at least one of the semiconductor substrate and the epitaxial layer.

3. The CMOS image sensor of claim 1, wherein the net n-type doping concentration has a maximum at the surface and decreasing monotonically with increasing distance from the surface within the semiconductor substrate and the epitaxial layer.

4. The CMOS image sensor of claim 1, wherein the p-type CMOS pixel comprises:
a highly p-doped sense node;
a PMOS reset transistor in signal communication with the sense node;
a PMOS source follower transistor in signal communication with the sense node;
a PMOS row select transistor in signal communication with the source follower transistor; and
a pinned-photodiode (PPD) in electrical communication with the sense node.

5. The CMOS image sensor of claim 4, further comprising a first charge transfer gate located between the sense node and the PPD.

6. The CMOS image sensor of claim 5, further comprising a second charge transfer gate located adjacent the phototransistor and distal to the first transfer gate and a highly p-doped contact for preventing charge carriers from blooming to the sense node.

7. The CMOS image sensor of claim 1, further comprising driver logic formed in the semiconductor substrate.

8. The CMOS image sensor of claim 7, wherein the driver logic is at least one of an address encoder, a pixel bipolar driver, and a multiplexor.

9. The CMOS image sensor of claim 1, wherein the p-type CMOS pixel comprises:
a highly p-doped sense node in the semiconductor substrate and positioned substantially in the center of the at least one CMOS pixel;
a transfer gate formed about the sense node; and
at least one photodiode formed about the transfer gate.

10. The CMOS image sensor of claim 9, further comprising:
a PMOS reset transistor in signal communication with the sense node;
a PMOS source follower transistor in signal communication with the sense node;
a PMOS row select transistor in signal communication with the source follower transistor; and
a pinned-photodiode (PPD) in electrical communication with the sense node.

11. The CMOS image sensor of claim 10, wherein the reset transistor, the source follower transistor, and the row select transistor are located substantially to one side of the at least one CMOS pixel substantially adjacent to the PPD.

12. The CMOS image sensor of claim 11, further comprising an implant formed about the photodiode operable to step potential in a direction toward the sense node.

13. The CMOS image sensor of claim 1, further comprising at least a portion of a buried oxide layer substantially underlying the semiconductor substrate distal to the surface.
